(19) United States
(12) Patent Application Publication
(10) Pub. No.: US 2005/0121685 A1
(43) Pub. Date: Jun. 9, 2005

(54) Flip-chip light emitting diode and method of manufacturing the same

(75) Inventors: Tae-yeon Seong, Gwangju-si (KR); June-o Song, Gwangju-si (KR); Dong-seok Leem, Gwangju-si (KR); Hyun-gi Hong, Gwangju-si (KR)

Correspondence Address: BURNS DOANE SWECKER & MATHIS L L P, POST OFFICE BOX 1404, ALEXANDRIA, VA, 22313-1404, US

(73) Assignees: Samsung Electronics Co., Ltd., Gyeonggi-do (KR); Gwangju Institute of Science and Technology, Gwangju-si (KR)

(21) Appl. No.: 10/981,502

(22) Filed: Nov. 5, 2004

(30) Foreign Application Priority Data
Nov. 28, 2003 (KR) 10-2003-0085600

(51) Int. Cl. H01L 33/00

(52) U.S. Cl. 257/99

(57) ABSTRACT

Provided are a flip-chip type light emitting device and a method of manufacturing the same. The provided flip-chip type light emitting device includes a substrate, an n-type cladding layer, an active layer, a p-type cladding layer, an ohmic contact layer formed of tin oxide to which at least one of antimony, fluorine, phosphorus, and arsenic is doped, and a reflection material formed of a reflective material. According to the provided flip-chip type light emitting device and the method of manufacturing the same, a current-voltage characteristic and durability are improved by applying a conductive oxide electrode structure having low surface resistivity and high carrier concentration.

### BACKGROUND OF THE INVENTION

This application claims the priority of Korean Patent Application No. 2003-85600, filed on Nov. 28, 2003, in the Korean Intellectual Property Office, the disclosure of which is incorporated herein in its entirety by reference.

1. Field of the Invention

The present invention relates to a flip-chip type light emitting device and a method of manufacturing the same, and more particularly, to a flip-chip type light emitting device for improving luminescence efficiency and a method of manufacturing the same.

2. Description of the Related Art

Conventional gallium nitride based light emitting devices are divided into top emitting type light emitting devices and flip-chip type light emitting devices. A top emitting type light emitting device emits light through an ohmic contact layer, which contacts a p-type cladding layer. In such a top emitting type light emitting device, an electrode structure is formed by sequentially depositing nickel and gold on a p-type cladding layer.

However, in the case of an electrode structure of nickel/gold, light generated in the electrode structure is absorbed in the electrode structure, because a thin layer is opaque, thus luminescence efficiency of a light emitting device is lowered. In other words, a top emitting type light emitting device cannot be used as a light emitting device having a large capacity and high luminance.

Accordingly, it is required to develop a flip-chip type light emitting device using silver (Ag) and aluminum (Al), which are spotlighted as high reflection materials, in order to realize a light emitting device having a large capacity and high luminance. U.S. Pat. No. 6,194,743 discloses a flip-chip type light emitting device with high efficiency by depositing a thick silver layer having a high reflection rate on a p-type cladding layer.

However, in such a flip-chip type light emitting device, adherence between the p-type cladding layer and the silver layer is weak, thus a large portion of the silver layer is oxidized or a large number of voids are formed in the silver layer after annealing, resulting in the increase of contact resistivity and the decrease of a reflection rate.

On the other hand, a flip-chip type light emitting device in which indium-tin-oxide (ITO) as a conductive oxide is used as an intermediate layer is provided to solve such a problem between a reflection layer and a p-type cladding layer. More specifically, such a flip-chip type light emitting device generates an excellent output characteristic compared to a conventional top emitting type light emitting device of a nickel/gold electrode structure. However, the operation voltage of the flip-chip light emitting device of ITO/Ag electrode structure rapidly increases due to the resistivity of ITO, which is higher than the resistivity of nickel/gold by more than three times.

### SUMMARY OF THE INVENTION

The present invention provides a flip-chip type light emitting device having an electrode structure of providing low contact resistivity and a high reflection rate and a method of manufacturing the same.

The present invention also provides a flip-chip type light emitting device having a low operation voltage and a high output characteristic and a method of manufacturing the same.

According to an aspect of the present invention, there is provided a flip-chip type light emitting device having an active layer interposed between an n-type cladding layer and a p-type cladding layer, comprising an ohmic contact layer formed of tin oxide to which an addition element is doped, on the p-type cladding layer and a reflection layer formed of a reflective material, on the ohmic contact layer.

The addition element may be at least one selected from the group consisting of antimony, fluorine, phosphorus, and arsenic.

In addition, the addition element may be added to a ratio of 0.1 to 40 atomic percents.

The reflective material may be at least one selected from the group consisting of silver and rhodium.

The flip-chip type light emitting device may further includ a diffusion barrier layer formed of any one selected from the group consisting of nickel, gold, zinc, copper, the alloy of zinc-nickel, the alloy of copper-nickel, the alloy of nickel-magnesium, and tin oxide to which the addition element is doped, on the reflection layer.

According to another aspect of the present invention, there is provided a method of manufacturing a flip-chip type light emitting device having an active layer interposed between an n-type cladding layer and a p-type cladding layer, comprising forming an ohmic contact layer by using addition element doped tin oxide on the p-type cladding layer of a light emitting structure, which is formed by sequentially depositing the n-type cladding layer, the active layer, and the p-type cladding layer on a substrate, forming a reflection layer formed of a reflective material on the ohmic contact layer, and annealing the resultant structure.

The addition element may be at least one selected from the group consisting of antimony, fluorine, phosphorus, and arsenic.

In addition, the method may further include forming a diffusion barrier layer by using any one selected from the group consisting of nickel, gold, zinc, copper, the alloy of zinc-nickel, the alloy of copper-nickel, the alloy of nickel-magnesium, and tin oxide to which the addition element is doped, on the reflection layer.

The forming of the ohmic contact layer may be performed by depositing under a vapor environment including oxygen.

In the forming of the ohmic contact layer, oxygen is supplied to the reactor at a pressure of 1 to 300 mTorr.

The annealing may be performed at a temperature of 200 to 800° C.

The annealing may be performed under a vapor environment including at least one of nitrogen, argon, helium, oxygen, hydrogen, and air for 10 seconds to 2 hours.

### BRIEF DESCRIPTION OF THE DRAWINGS

The above and other features and advantages of the present invention will become more apparent by describing in detail exemplary embodiments thereof with reference to the attached drawings in which:

FIG. 1 is a sectional view of a p-type electrode structure according to a first embodiment of the present invention;

FIG. 2 is a sectional view of a p-type electrode structure according to a second embodiment of the present invention;

FIG. 3 is a graph illustrating the changes in resistivity and a carrier concentration of antimony doped tin oxide, which is used in a p-type electrode structure according to the present invention, after annealing;

FIG. 4 is a graph illustrating the result of an X-ray diffraction experiment performed on antimony doped tin oxide, which is used in a p-type electrode structure according to the present invention;

FIG. 5 is a graph illustrating the transmittance of antimony doped tin oxide, which is used in a p-type electrode structure according to the present invention;

FIG. 6 is a graph illustrating current-voltage characteristics of a p-type electrode structure according to the first embodiment of the present invention, before and after annealing;

FIG. 7 is a graph illustrating the result of an Auger Electron Spectroscopy (AES) about a p-type electrode structure according to the first embodiment of the present invention;

FIGS. 8A through 8C are scanning electron microscopes (SEMs) of a conventional silver electrode structure and a p-type electrode structure according to the first embodiment of the present invention;

FIG. 9 is a sectional view of a light emitting device to which a p-type electrode structure according to the first embodiment of the present invention is applied;

FIG. 10 is a sectional view of a light emitting device to which a p-type electrode structure according to the second embodiment of the present invention is applied;

FIG. 11 is a graph illustrating an operation voltage of a blue light emitting device of InGaN/GaN MQW structure to which a p-type electrode structure according to the present invention is applied, after annealing; and

FIG. 12 is a graph illustrating an output characteristic of a blue light emitting device of InGaN/GaN MQW structure to which a p-type electrode structure according to the present invention is applied, after annealing.

### DETAILED DESCRIPTION OF THE INVENTION

The present invention will now be described more fully with reference to the accompanying drawings, in which exemplary embodiments of the invention are shown.

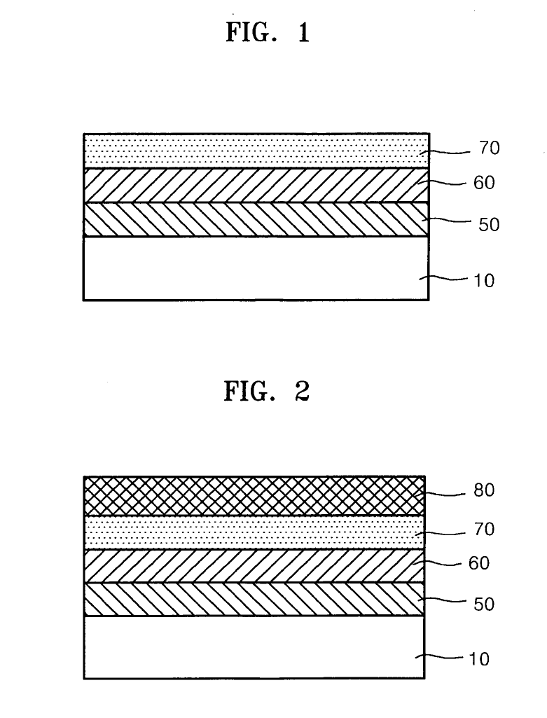

FIG. 1 is a sectional view of a p-type electrode structure according to a first embodiment of the present invention.

Referring to FIG. 1, a p-type electrode structure includes an ohmic contact layer 60 and a reflection layer 70.

In the p-type electrode structure of FIG. 1, a nitride based group III cladding layer 50 is formed on a substrate 10, and the ohmic contact layer 60 and the reflection layer 70 are sequentially deposited on the p-type cladding layer 50.

The p-type cladding layer 50 is formed of a group III nitride compound to which a p-type dopant is doped.

The group III nitride compound denotes a compound represented by AlₓIn_{y}Ga_{z}N (0≦×≦1, 0≦y≦1, 0z≦1, 0≦x+y+z≦1).

In addition, examples of the p-type dopant include Mg, Zn, Ca, Xr, and Ba.

The ohmic contact layer 60 is formed of tin oxide to which an addition element is doped.

An example of the addition element doped to the ohmic contact layer 60 is at least one of antimony (Sb), fluorine (F), phosphorus (P), and arsenic (As).

The addition ratio of the addition element, which is doped to the tin oxide, is 0.01 to 40 atomic percent. The atomic percent denotes the ratio of the numbers of the addition elements.

In general, an undoped tin oxide (SnO₂) has high resistivity of tens to hundreds ohms (Ω-cm) and a low carrier concentration.

On the other hand, the resistivity of the oxide can be lowered by annealing the oxide at a high temperature after depositing at a normal temperature, or by depositing at a temperature higher than a normal temperature. However, a conductive oxide formed under such a condition still has relatively high resistivity of plural to tens ohms (Ω-cm).

Thus, it is difficult to use an undoped tin oxide only for an ohmic contact layer.

In the embodiments of the present invention, addition elements such as antimony, fluorine, phosphorus, and arsenic are doped to the tin oxide to lower the resistivity of the tin oxide.

In addition, when the doped oxide is annealed after being deposited or deposited at a temperature of higher than a normal temperature, low resistivity of lower than 10⁻² Ω-cm can be obtained.

The ohmic contact layer 60 may be formed to a thickness of 0.1 to 500 nanometers.

The reflection layer 70 may be formed of a material having a high reflection rate of over 85% in visible ray and ultraviolet ray ranges, for example, such as one of silver and rhodium.

In addition, the reflection layer 70 may be formed to a thickness of 10 to 2,000 nanometers.

FIG. 2 is a sectional view of a p-type electrode structure according to a second embodiment of the present invention.

In the description of a p-type electrode according to the second embodiment of the present invention of FIG. 2, the elements having the same functions as FIG. 1 are referred to the same reference numerals as FIG. 2.

Referring to FIG. 2, a p-type electrode structure according to the second embodiment of the present invention includes an ohmic contact layer 60, a reflection layer 70, and a diffusion barrier layer 80.

In the p-type electrode structure of FIG. 2, a nitride based group III cladding layer 50 is formed on a substrate 10, and the ohmic contact layer 60, the reflection layer 70, and the diffusion barrier layer 80 are sequentially deposited on the p-type cladding layer 50.

The ohmic contact layer 60 is formed by doping at least one of antimony, fluorine, phosphorus, and arsenic to tin oxide.

The reflection layer 70 is formed of silver or rhodium, as in the case of the first embodiment of the present invention.

The diffusion barrier layer 80 may be formed of any one selected from the group consisting of nickel, gold, zinc, copper, the alloy of zinc-nickel, the alloy of copper-nickel, the alloy of nickel-magnesium, and tin oxide to which an addition element including at least one of antimony, fluorine, phosphorus, and arsenic is doped.

The diffusion barrier layer 80 may be formed to a thickness of 1 to 1,000 nanometers.

The p-type electrode structures of FIGS. 1 and 2, in other words, the p-type electrode structure formed of the ohmic contact layer 60 and the reflection layer 70 and the p-type electrode structure formed of the ohmic contact layer 60, the reflection layer 70, and the diffusion barrier layer 80 are annealed after being deposited.

First, the deposition processes may be performed by any one of e-beam or thermal evaporator, sputtering deposition, and pulsed laser deposition.

The ohmic contact layer 60 may be deposited by supplying oxygen under 1 to 300 mTorr to a reactor of an evaporator.

In addition, the annealing is performed under a vacuum or gas environment at a temperature of 200 to 800° C. for 10 seconds to 2 hours.

In this case, at least one of nitrogen, argon, helium, oxygen, hydrogen, and air is input to the reactor in the annealing process.

FIG. 3 is a graph illustrating changes in resistivity and a carrier concentration after annealing an ohmic contact layer 60 formed of tin oxide to which antimony of 5 atomic percent is doped (5 at %Sb—SnO₂) according to the embodiment of the present invention. In FIG. 3, the graph denoted by reference character a is about the resistivity and the graph denoted by reference character b is about the carrier concentration.

The ohmic contact layer 60 of the graph of FIG. 3 was obtained by doping antimony to tin oxide having a thickness of 300 nm under an oxygen pressure of 30 mTorr by using a laser evaporator, and annealing at a temperature of 400 to 600° C. Thereafter, the changes in the resistivity and the carrier concentration according to the annealing process were measured by using a hall measurer.

Referring to the graph of FIG. 3, as an annealing temperature is increased, the resistivity is lowered and the carrier concentration is increased. In other words, when the antimony doped tin oxide is deposited at a normal temperature under an oxygen environment by using a laser evaporator and annealed at a temperature of 400 to 600° C., the resistivity becomes as small as 7.06×10⁻³ to 2.62×10⁻³ Ω-cm.

Table 1 denotes the result of experiments performed on undoped tin oxide (SnO₂) and antimony doped tin oxide (sb—SnO₂), which is obtained by using a laser evaporator under various conditions.

TABLE 1

| | | Sb doped SnO₂ | | |
|---|---|---|---|---|
| | | | | normal |
| | | | normal | temperature |
| | SnO₂ | | temperature | growth |
| | 600° C. | | growth (O₂) - | (vacuum) - |
| | growth | 600° C. | 600° C. | 600° C. |
| | (O₂) | growth (O₂) | annealing | annealing |
| R (Ω-cm) | 2-6.5 | 3.01 × 10⁻³ | 2.62 × 10⁻³ | 1.74 × 10⁻¹ |
| N (cm⁻³) | — | 3.96 × 10⁻²⁰ | 4.33 × 10⁻²⁰ | 6.40 × 10⁻¹⁸ |

In Table 1, R denotes resistivity and N denotes carrier concentration.

Referring to Table 1, even when the undoped tin oxide is deposited at a temperature of 600° C., which is higher than a normal temperature, the resistivity of the undoped tin oxide is as high as plural ohms.

On the other hand, when the antimony doped tin oxide is deposited under the same condition as the undoped tin oxide, the resistivity is as low as 3.01×10⁻³ Ω-cm. In addition, when the antimony doped tin oxide is deposited at a normal temperature and annealed, the resistivity is as low as 2.62×10⁻³ Ω-cm.

When the antimony doped tin oxide is deposited under a vacuum environment, the resistivity is relatively high as 1.74×10⁻¹ Ω-cm. Based on the result of the experiment, it is better to deposit an ohmic contact layer 60 under an oxygen environment.

In other words, when oxygen is not injected when depositing an ohmic contact layer 60, an oxygen deficiency occurs and the resistivity of the deposited layer is suddenly increased, thus the carrier concentration of the layer is lowered.

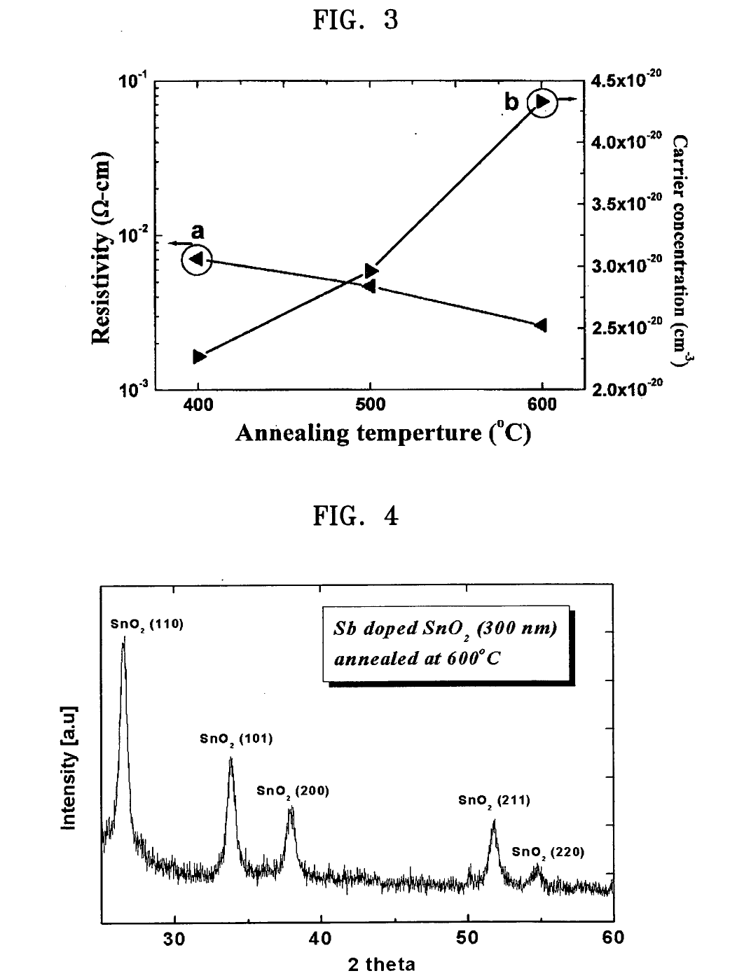

FIG. 4 is a graph illustrating the result of an X-ray diffraction experiment performed on antimony doped tin oxide, which is formed at a normal temperature under an oxygen environment to a thickness of about 300 nm and annealed at a temperature of 600° C. Referring to the graph of FIG. 4, the peaks of the antimony doped tin oxide are significantly detected.

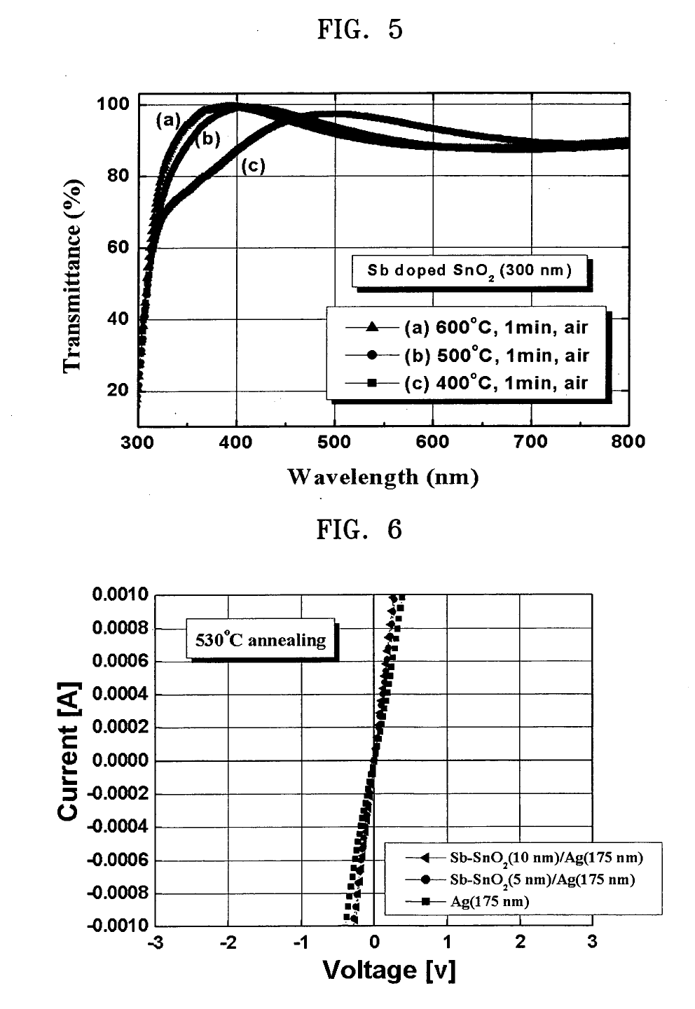

FIG. 5 is a graph illustrating optical transmittances of antimony doped tin oxides, which are deposited at a normal temperature under an oxygen environment to a thickness of about 300 nm and annealed at temperatures of 400 to 600° C. Referring to the graph of FIG. 5, the antimony doped tin oxides have the transmittances of higher than 85% over a large area of 400 to 800 nm.

FIG. 6 is a graph illustrating electric characteristics of electrode structures, which are formed by depositing ohmic contact layers 60 having thicknesses of 5 nm and 10 nm and reflection layers 70 having a thickness of 175 nm on p-type cladding layers 50 and annealing, respectively. In this case, the p-type cladding layer 50 is formed of gallium nitride having a carrier concentration of 5×10¹⁷ cm⁻³. The ohmic contact layer 60 is formed of antimony doped tin oxide, which is deposited at a normal temperature under an oxygen environment, and the reflection layer 70 is formed of silver. In addition, the annealing is performed at a temperature of 530° C. under an air environment.

Even not shown in the graph of FIG. 6, the antimony doped tin oxide, which is deposited at a normal temperature, has relatively high resistivity and represents rectifying conduct before annealing; however, the antimony doped tin oxide represents linear current-voltage characteristic of denoting an ohmic contact conduct and has low non-contact resistivity of 10⁻⁴ Ωcm² after annealing.

On the other hand, when the non-contact resistivity of an ohmic electrode layer formed of silver is calculated, the non-contact resistivity is as high as 3×10⁻³ Ωcm².

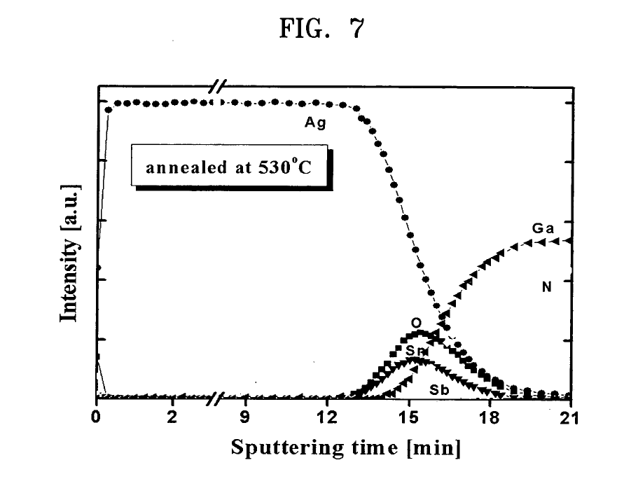

FIG. 7 is a graph illustrating the result of auger electron spectroscopy (AES) of a p-type electrode structure in which antimony doped tin oxide and silver are sequentially formed according to the embodiment of the present invention. Referring to FIG. 7, the definite elements and boundaries of gallium and nitrogen are detected, as well as silver, tin, and antimony.

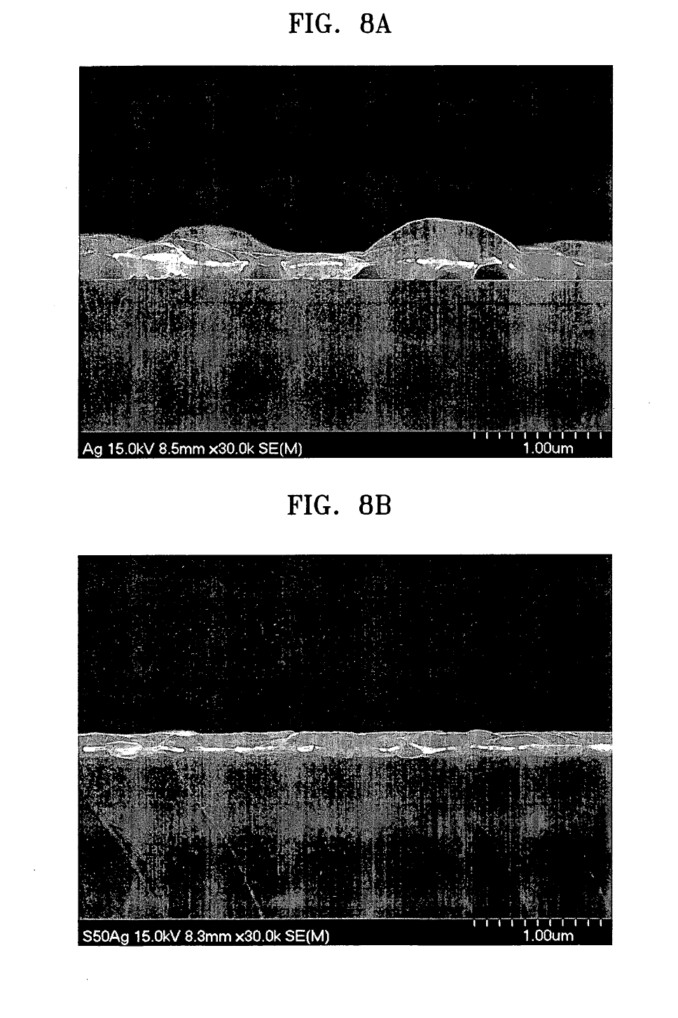

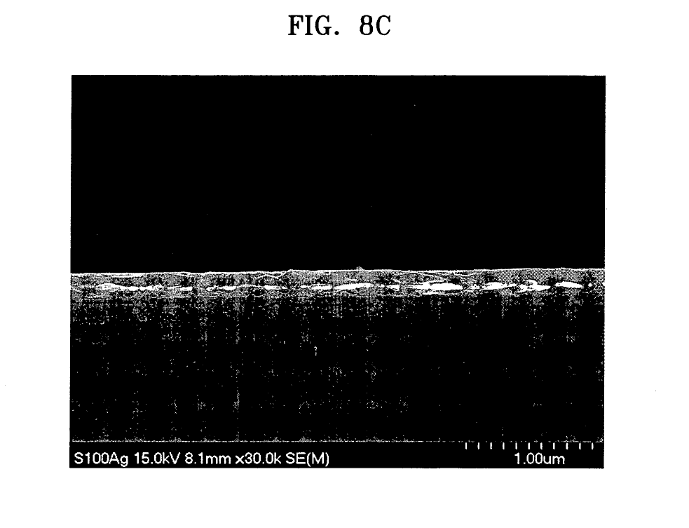

FIG. 8A is a scanning electron microscopy (SEM) photograph of a conventional electrode structure, which is formed of silver only and annealed at a temperature of 530° C. FIG. 8B is an SEM photograph of an electrode structure, which is formed of a p-type cladding layer 50 of p-type gallium nitride (GaN), an ohmic contact layer 60 of antimony doped tin oxide having a thickness of 5 nm, and a reflection layer 70 of silver having a thickness of 175 nm and annealed at a temperature of 530° C., according to the embodiment of the present invention. FIG. 8C is an SEM photograph of an electron structure, which is formed of a p-type cladding layer of p-type gallium nitride, an ohmic contact layer 60 of antimony doped tin oxide having a thickness of 10 nm, and a reflection layer 70 of silver having a thickness of 175 nm and annealed at a temperature of 530° C., according to the embodiment of the present invention.

Referring to the SEM photograph of FIG. 8A, the boundaries of gallium nitride are remarkably swelled up while having voids due to the contact characteristic between silver and gallium nitride. Such a result is directly related to the high non-contact resistivity of the electrode structure formed of silver only.

On the other hand, referring to the SEM photographs of FIGS. 8B and 8C, when forming the ohmic contact layer 60 of antimony doped tin oxide and the silver reflection layer 70, and annealing the structure at a temperature of 530° C., voids are not formed and swelling phenomenon is not generated due to the excellent contact characteristic between the p-type cladding layer 50 and the electrode structure.

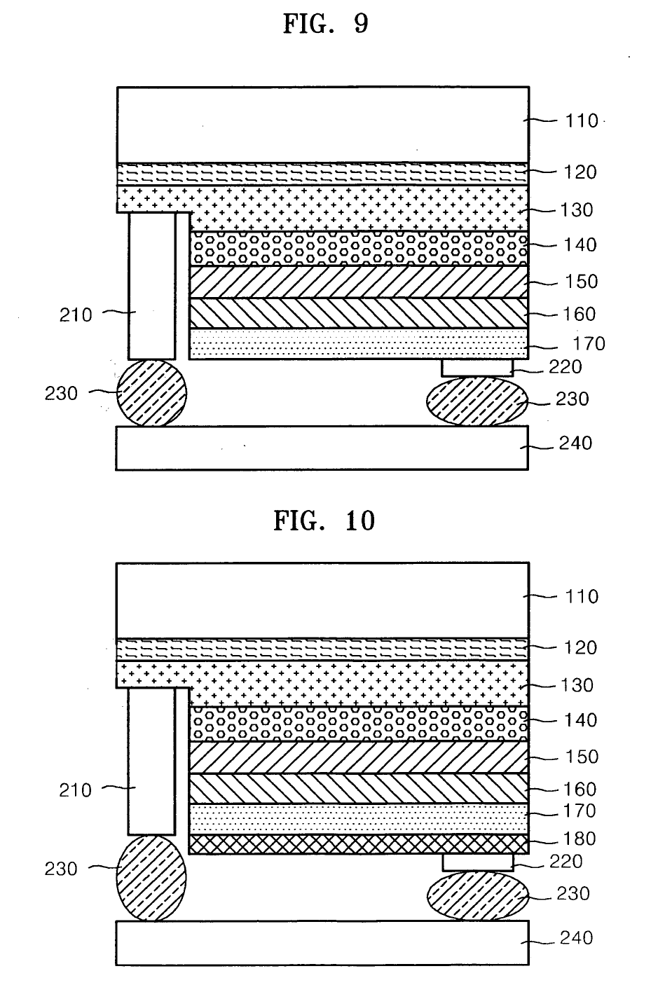

FIG. 9 is a sectional view of a flip-chip type light emitting device to which a p-type electrode structure of FIG. 1 is applied in a reverse state, according to the first embodiment of the present invention.

Referring to FIG. 9, a light emitting device is formed of a transparent substrate 110, a buffer layer 120, an n-type cladding layer 130, an active layer 140, a p-type cladding layer 150, an ohmic contact layer 160, and a reflection layer 170 that are deposited in a vertical direction. In FIG. 9, reference numeral 210 denotes an n-type electrode pad, 220 denotes a p-type electrode pad, 230 denotes a solder, which is required for a flip-chip type light emitting device, and 240 denotes a submount.

The substrate 110 is formed of a transparent material, for example, sapphire or silicon carbide (SiC).

The buffer layer 120 may be omitted.

Each layer of the buffer layer 120 through the p-type cladding layer 150 is formed of a compound selected from compounds represented as AlₓIn_{y}Ga_{z}N (0≦x≦1, 0≦y≦1, 0≦z≦1, 0≦x+y+z≦1), which is a general formula of a nitride based group III compound. In addition, the n-type cladding layer 130 and the p-type cladding layer 150 are formed by adding corresponding dopants.

The active layer 150 may be formed by a single layer or an MQW layer.

For example, when a gallium nitride semiconductor is applied to a light emitting device, a buffer layer 120 is formed of gallium nitride. In addition, an n-type cladding layer 130 is formed of gallium nitride to which Si, Ge, Se, or Te is added as an n-type dopant, an active layer 140 is formed of InGaN/GaN or AlGaN/GaN MQW, and a p-type cladding layer 150 is formed of gallium nitride to which Mg, Zn, Ca, Sr, or Ba is added as a p-type dopant.

An n-type ohmic contact layer (not shown) may be interposed between the n-type cladding layer 130 and the n-type electrode pad 210, and the n-type ohmic contact layer may be formed by various structures, for example, sequentially depositing titanium and aluminum.

The p-type electrode pad 220 may be formed by various structures, for example, sequentially depositing nickel and gold.

The ohmic contact layer 160 is formed of tin oxide to which an addition element is doped, as described with reference to FIG. 1.

The addition element includes at least one of antimony, fluorine, phosphorus, and arsenic.

In addition, the reflection layer 170 is formed of at least one of silver and rhodium having a high reflection rate, as described with reference to FIG. 1.

The layers are formed by an e-beam evaporator, physical vapor deposition (PVD), chemical vapor deposition (CVD), plasma laser deposition (PLD), a dual-type thermal evaporator, or sputtering. More specifically, when depositing nitride oxide including an addition element for forming the ohmic contact 160, oxygen may be injected at a pressure of 1 to 300 mTorr.

Such a light emitting device is manufactured by forming a light emitting structure including a substrate 110 through a p-type cladding layer 150, forming an ohmic contact layer 160 of tin oxide to which an addition element on the p-type cladding layer 150, and sequentially depositing a reflection layer 170 of silver or rhodium. Thereafter, the structure is annealed.

FIG. 10 is a sectional view of a light emitting device formed by interposing a diffusion barrier layer 180 between the reflection layer 170 and the p-type electrode pad 220 of FIG. 9. The same elements as FIG. 9 are referred to as the same reference numerals.

A diffusion barrier layer 180 induces an excellent contact characteristic between the reflection layer 170 of silver or rhodium and the p-type electrode pad 220. More specifically, the diffusion barrier layer 180 prevents the diffusion of the material of the p-type electrode pad 220 to the reflection layer 170 in order to prevent the increase of ohmic contact resistivity and the decrease of a reflection rate.

The light emitting device of FIG. 10 is manufactured by forming a light emitting structure including a substrate 110 through a p-type cladding layer 150, forming an ohmic contact layer 160 of tin oxide to which an addition element is doped on the p-type cladding layer, and depositing a reflection layer 170 of silver or rhodium. Thereafter, a diffusion barrier layer 180, which is formed of any one of tin oxide to which an addition element is doped, nickel, gold, zinc, copper, the alloy of zinc-nickel, the alloy of copper-nickel, and the alloy of nickel-magnesium, and the structure is annealed.

The addition element added to the tin oxide of the diffusion barrier layer 180 is at least one of antimony, fluorine, phosphorus, and arsenic.

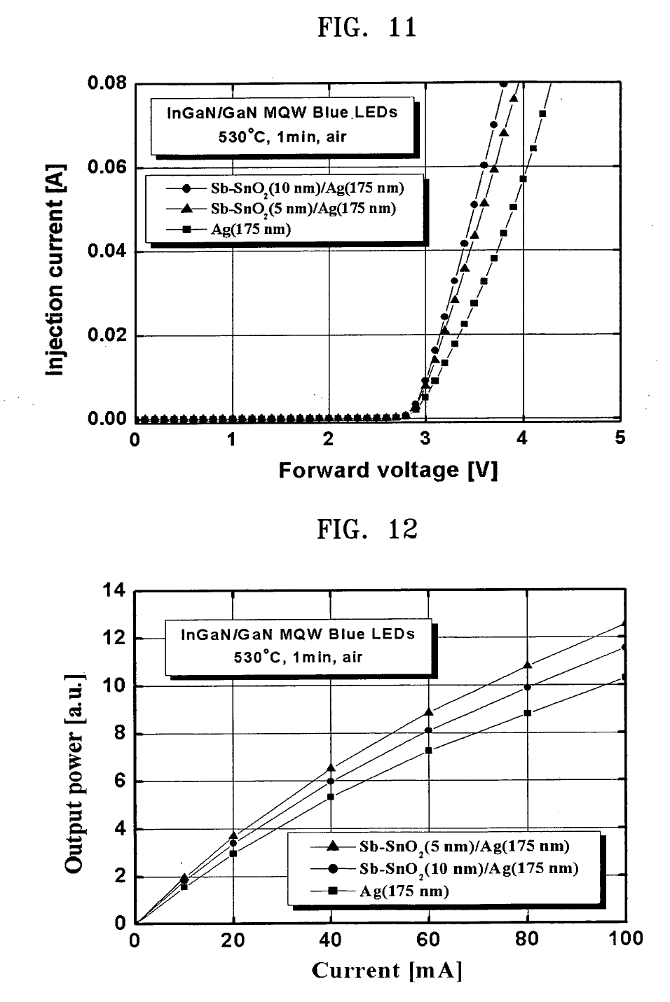

FIG. 11 is a graph illustrating the operation voltages of blue light emitting devices of InGaN/GaN MQW structure to which the electrode structure of FIG. 9 is applied. In this case, the electrode structure is annealed at a temperature of 530° C. under an air environment. In addition, the graph illustrating the operation voltage of a conventional light emitting device having a silver electrode structure is included in FIG. 11.

Referring to FIG. 11, the operation voltages of the light emitting devices to which electrode structures including ohmic contact layers of antimony doped tin oxide having thicknesses of 5 nm and 10 nm and silver layers having a thickness of 175 nm are applied are 3.16 V and 3.18V at 20 mA, respectively. However, the operation voltage of a conventional light emitting device including a conventional electrode structure having a silver layer with a thickness of 175 nm is 3.36 V. As a result, the operation voltages of the light emitting devices according to the embodiment of the present invention are remarkably lower than the operation voltage of the conventional light emitting device.

FIG. 12 is a graph illustrating the output characteristic of the blue light emitting device of InGaN/GaN MQW structure, which is used for the experiment of FIG. 11.

Referring to the graph of FIG. 12, the output characteristic of the light emitting device to which the electrode structure including antimony doped tin oxide is applied according to the embodiment of the present invention is better than the output characteristic of the conventional light emitting device to which the silver electrode structure is applied, over the range of less than 100 mA.

As described above, according to a flip-chip type light emitting device and a manufacturing method of the same, a current-voltage characteristic and durability are improved by applying a conductive oxide electrode structure having low surface resistivity and high carrier concentration.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A flip-chip type light emitting device having an active layer interposed between an n-type cladding layer and a p-type cladding layer, the flip-chip type light emitting device comprising:
an ohmic contact layer formed of tin oxide to which an addition element is doped, on the p-type cladding layer; and
a reflection layer formed of a reflective material, on the ohmic contact layer.

2. The flip-chip type light emitting device of claim 1, wherein the addition element is at least one selected from the group consisting of antimony, fluorine, phosphorus, and arsenic.

3. The flip-chip type light emitting device of claim 2, wherein the addition element is added to a ratio of 0.1 to 40 atomic percents.

4. The flip-chip type light emitting device of claim 1, wherein the reflective material is at least one selected from the group consisting of silver and rhodium.

5. The flip-chip type light emitting device of claim 1 further including a diffusion barrier layer formed of any one selected from the group consisting of nickel, gold, zinc, copper, the alloy of zinc-nickel, the alloy of copper-nickel, the alloy of nickel-magnesium, and tin oxide to which the addition element is doped, on the reflection layer.

6. The flip-chip type light emitting device of claim 5, the addition element is at least one selected from the group consisting of antimony, fluorine, phosphorus, and arsenic.

7. A method of manufacturing a flip-chip type light emitting device having an active layer interposed between an n-type cladding layer and a p-type cladding layer, the method comprising:
forming an ohmic contact layer by using addition element doped tin oxide on the p-type cladding layer of a light emitting structure, which is formed by sequentially depositing the n-type cladding layer, the active layer, and the p-type cladding layer on a substrate;
forming a reflection layer formed of a reflective material on the ohmic contact layer; and
annealing the resultant structure.

8. The method of claim 7, wherein the addition element is at least one selected from the group consisting of antimony, fluorine, phosphorus, and arsenic.

9. The method of claim 7, wherein the reflective material is at least one selected from the group consisting of silver and rhodium.

10. The method of claim 7 further including forming a diffusion barrier layer by using any one selected from the group consisting of nickel, gold, zinc, copper, the alloy of zinc-nickel, the alloy of copper-nickel, the alloy of nickel-magnesium, and tin oxide to which the addition element is doped, on the reflection layer.

11. The method of claim 10, wherein the addition element is at least one selected from the group consisting of antimony, fluorine, phosphorus, and arsenic.

12. The method of claim 7, wherein the annealing is performed at a temperature of 200 to 800° C.

13. The method of claim 7, wherein the forming of the ohmic contact layer is performed by depositing under a vapor environment including oxygen.
